(19) United States
(12) Patent Application Publication
(10) Pub. No.: US 2018/0076816 A1
(43) Pub. Date: Mar. 15, 2018

(54) TEMPERATURE MEASUREMENT CIRCUIT, INTEGRATED CIRCUIT, AND TEMPERATURE MEASUREMENT METHOD

(71) Applicant: Renesas Electronics Corporation, Tokyo (JP)

(72) Inventor: Tomokazu MATSUZAKI, Tokyo (JP)

(73) Assignee: Renesas Electronics Corporation, Tokyo (JP)

(21) Appl. No.: 15/652,843

(22) Filed: Jul. 18, 2017

(30) Foreign Application Priority Data
Sep. 15, 2016 (JP) 2016-180543

(51) Int. Cl. H03L 1/02; H03B 5/32; G01K 7/32

(52) U.S. Cl. CPC H03L 1/026; G01K 7/32; H03B 5/32

(57) ABSTRACT

It is possible to flexibly respond to accuracy required for a temperature sensor. An oscillator 11 generates a clock signal. The oscillator 11 is configured to be capable of changing a relationship between a frequency of the clock signal and a temperature. A counter 13 is configured to count the clock signal generated by the oscillator 11 by using a reference signal having a frequency not changing depending on a temperature. A CPU 16 generates temperature information based on the relationship between the frequency of the clock signal and the temperature in the oscillator 11 and a count value of the counter 13. The control circuit 14 changes the relationship between the frequency of the clock signal and the temperature in the oscillator 11 when the counter 13 overflows.

### CROSS-REFERENCE TO RELATED APPLICATIONS

This application is based upon and claims the benefit of priority from Japanese patent application No. 2016-180543, filed on Sep. 15, 2016, the disclosure of which is incorporated herein in its entirety by reference.

### BACKGROUND

The present disclosure relates to a temperature measurement circuit, an integrated circuit, and a temperature measurement method, and for example, a temperature measurement circuit and an integrated circuit including an oscillator that generates a signal having a frequency dependent on a temperature, and a temperature measurement method in such a temperature measurement circuit and an integrated circuit.

Renesas Electronics Co. discloses, in “RL78/I1E User's Manual Hardware Rev. 1.00” (Chapter 15 Temperature Sensor, July 2015), a microcomputer including a temperature sensor. In this document, the temperature sensor measures a temperature by monitoring output voltages (Vf1 and Vf2) of two diodes having temperature characteristics (temperature dependencies) different from each other. Alternatively, the temperature sensor measures temperature by monitoring a constant voltage (Vref) output from a BGR (Band Gap Reference) circuit and an output voltage (Vf2) of a diode. In this document, an ADC (Analog to Digital Converter) is used for voltage monitoring.

Shor et al. disclose, in “Ratiometric BJT-Based Thermal Sensor in 32 nm and 22 nm Technologies”, ISSCC 2010/SESSION 11/SENSORS & MEMS/11.8, 2012 IEEE International Solid-State Circuits Conference, a temperature sensor to which V-F (Voltage Frequency) conversion is applied. In this document, a reference voltage (Vref) output from a BGR circuit and a diode output voltage (Vbe) are used as reference voltages of an RS (Reset Set) latch oscillator. The diode output voltage Vbe has a temperature characteristic, and an oscillation frequency of an oscillator varies depending on a temperature. The reference voltage Vref and the diode output voltage Vbe are chopped and then input to a comparator. An output of the oscillator is connected to a counter. The temperature can be obtained by a count value of the counter.

### SUMMARY

However, the present inventor has found a problem that it is difficult for the temperature sensors disclosed by Renesas Electronics Co. and Shor et al. to flexibly respond to accuracy required for a temperature sensor.

Other problems of the related art and new features of the present disclosure will become apparent from the following descriptions of the specification and attached drawings.

According to an example aspect, in a temperature measurement circuit and a temperature measurement method, one of a clock signal in which a relationship between a frequency thereof and a temperature can be changed and a reference signal having a frequency not changing depending on the temperature is counted by using the other, and the relationship between the frequency of the clock signal and the temperature is changed when a counter overflows.

According to another example aspect, an integrated circuit includes a temperature measurement circuit that counts one of a clock signal in which a relationship between a frequency thereof and a temperature can be changed and a reference signal having a frequency not changing depending on the temperature by using the other, and changes the relationship between the frequency of the clock signal and the temperature when a counter overflows and a processor that operates according to the clock signal or the reference signal. When an operation mode is set to a temperature measurement mode, a clock signal having a frequency dependent on a temperature is generated, and when the operation mode is set to a normal mode, a clock signal having a frequency not dependent on the temperature is generated.

According to the above example aspects, the temperature measurement circuit, the integrated circuit, and the temperature measurement method can flexibly respond to accuracy required for a temperature sensor.

### BRIEF DESCRIPTION OF THE DRAWINGS

The above and other aspects, advantages and features will be more apparent from the following description of certain embodiments taken in conjunction with the accompanying drawings, in which:

FIG. 1 is a block diagram showing a microcomputer unit including a temperature measurement circuit according to a first embodiment;

FIG. 2 is a block diagram showing an example of a configuration of an oscillator;

FIG. 3 is a graph showing an example of a relationship between a frequency of a clock signal and a temperature;

FIG. 4 is a graph showing another example of the relationship between a frequency of a clock signal and a temperature;

FIG. 5 is a graph showing a relationship between a temperature and a frequency of a clock signal;

FIG. 6A is a timing chart showing an example of a reference signal and a clock signal;

FIG. 6B is a timing chart showing an example of a reference signal and a clock signal;

FIG. 6C is a timing chart showing an example of a reference signal and a clock signal;

FIG. 7A is a timing chart showing another example of a reference signal and a clock signal;

FIG. 7B is a timing chart showing another example of a reference signal and a clock signal;

FIG. 7C is a timing chart showing another example of a reference signal and a clock signal;

FIG. 8 is a flowchart showing a procedure of temperature measurement;

FIG. 9 is a block diagram showing a microcomputer unit including a temperature measurement circuit according to a second embodiment;

FIG. 10 is a block diagram showing a microcomputer unit including a temperature measurement circuit according to a third embodiment; and

FIG. 11 is a flowchart showing an operation procedure of an MCU according to other embodiments.

### DETAILED DESCRIPTION

Following is a description of how the inventor has achieved the embodiments prior to the description of embodiments. Renesas Electronics Co. describes that an adjustment is performed as follows in order to improve the measurement accuracy of the temperature sensor.

A potential difference between Vf1 and Vf2 or a potential difference between Vref and Vf2 is monitored by using a gain adjustment function of PGA (programmable gain instrumentation amplifier) (gain adjustment).

The voltages Vf1, Vf2, and Vref are monitored with an offset generated by the PGA (offset adjustment).

However, the above gain adjustment and the offset adjustment may deteriorate the accuracy due to complicated circuit and increased circuit size. Additionally, a temperature may not be measured because it does not fall within a particular temperature input range. For this reason, it is difficult for the temperature sensor disclosed by Renesas Electronics Co. to flexibly respond to the required accuracy.

With regard to the temperature sensor disclosed by Shor et al., the gradient (slope) in the temperature characteristic of the diode output voltage Vbe is important for the temperature measurement accuracy. If accuracy is required, the slope of Vbe with respect to temperature may be increased, and if accuracy is not required, the slope of Vbe with respect to temperature may be reduced. However, in the temperature sensor disclosed by Shor et al., a change in the slope of Vbe causes the slope of Vref to be changed. Therefore, it is difficult for the temperature sensor disclosed by Shor et al. to flexibly respond to the required accuracy.

Hereinafter, embodiments incorporating means for solving the above-described problem will be described in detail with reference to the drawings. For the clarification of the description, the following description and the drawings may be omitted or simplified as appropriate. Further, each element shown in the drawings as functional blocks that perform various processing can be formed of a CPU (Central Processing Unit), a memory, and other circuits in hardware and may be implemented by programs loaded in the memory in software. Those skilled in the art will therefore understand that these functional blocks may be implemented in various ways by only hardware, only software, or the combination thereof without any limitation. Throughout the drawings, the same components are denoted by the same reference symbols and overlapping descriptions will be omitted as appropriate.

The above program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM) , flash ROM, RAM (random access memory) , etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line.

The invention will be described by dividing it into a plurality of sections or embodiments whenever circumstances require it for convenience in the following embodiments. However, unless otherwise particularly specified, these sections or embodiments are not irrelevant to one another. One section or embodiment is related to modifications, applications, details, supplementary explanations, and the like of some or all of the other ones. When reference is made to the number of elements or the like (including the number of pieces, numerical values, quantity, range, etc.) in the following embodiments, the number thereof is not limited to a specific number and may be greater than or less than or equal to the specific number unless otherwise particularly specified and definitely limited to the specific number in principle.

Further, in the following embodiments, components (including operation steps, etc.) are not always essential unless otherwise particularly specified and considered to be definitely essential in principle. Similarly, when reference is made to the shapes, positional relations, or the like of the components or the like in the following embodiments, they will include ones, for example, substantially approximate or similar in their shapes or the like unless otherwise particularly specified and considered not to be definitely so in principle. This is similarly applied even to the above-described number or the like (including the number of pieces, numerical values, quantity, range, etc.).

### First Embodiment

FIG. 1 shows a microcomputer unit (integrated circuit) including a temperature measurement circuit according a first embodiment. An MCU (Micro Computer Unit) 10 includes an oscillator 11, an oscillator 12, a counter 13, a control circuit 14, a memory 15, and a CPU 16. The oscillator 11, the oscillator 12, the counter 13, the control circuit 14, the memory 15, and the CPU 16 are used as a temperature measurement circuit according to this embodiment.

### [Overall Configuration]

The oscillator 11 generates a clock signal. The oscillator 11 is configured in such a way that a relationship between a frequency of a clock signal to be generated and a temperature can be changed. In other words, the oscillator 11 is configured such that the temperature characteristic of its oscillation frequency can be arbitrarily changed. The oscillator 11 is configured such that a ratio of a change in the frequency of the clock signal for a change in the temperature (temperature slope) can be changed. Alternatively or additionally, the oscillator 11 may be configured such that the relationship between the temperature and the frequency of the clock signal can be changed while maintaining the ratio of a change in the frequency of the clock signal for a change in the temperature constant. An oscillator disclosed in, for example, Japanese Unexamined Patent Application Publication No. 2012-212352 may be used for the oscillator 11.

The oscillator 12 generates a reference signal of a predetermined frequency (another clock signal). The oscillator 12 is configured as an oscillator for generating a reference signal having a frequency that does not change depending on the temperature. For example, a trimming-controlled RC oscillator or LC oscillator can be used for the oscillator 12. Note that it is not necessary for the reference signal to have no temperature characteristic at all in a strict manner. The temperature characteristic of the reference signal may be sufficiently lower than that of clock signal generated by the oscillator 11.

The counter 13 counts the number of pulses of the clock signal generated by the oscillator 11 by using the reference signal generated by the oscillator 12. The counter 13 counts the number of pulses included in the clock signal, for example, for a predetermined time defined based on the reference signal. A count value of the counter 13 corresponds to the frequency of the clock signal generated by the oscillator 11. If the clock signal generated by the oscillator 11 has a temperature characteristic, the count value varies depending on the temperature.

The CPU (processor) 16 has, for example, a register and an arithmetic unit. In this embodiment, the CPU 16 functions also as a temperature calculator for generating temperature information corresponding to the temperature. The CPU 16 generates the temperature information based on the relationship between the frequency of the clock signal and the temperature in the oscillator 11 and the count value of the counter 13. To be more specific, the CPU 16 calculates the frequency of the clock signal generated by the oscillator 11, for example, based on the count value of the counter 13. The CPU 16 identifies the temperature from the calculated frequency of the clock signal by using the relationship between the temperature and the frequency of the clock signal in the oscillator 11, and generates the temperature information indicating the identified temperature.

The control circuit (control unit) 14 controls the oscillators 11 and 12. The control circuit 14 further controls the counter 13 to start and stop counting. The control circuit 14, for example, periodically controls the counter 13 to start counting and/or controls the counter 13 to start counting when a predetermined event occurs. After the counter 13 starts the counting, the control circuit 14 determines as to whether or not the counter 13 has overflowed. When the counter 13 has overflowed, the control circuit 14 controls the oscillator 11 in order to change the relationship between the frequency of the clock signal and the temperature. The control circuit 14 holds, for example, a plurality of preset settings defining the relationship between the frequency of the clock signal and the temperature in the oscillator 11. The control circuit 14 controls the oscillator 11 according to the setting selected from the plurality of preset settings.

The memory (storage unit) 15 stores a parameter of a function indicating the relationship between the frequency of the clock signal and the temperature in the oscillator 11. For example, the memory 15 stores a plurality of parameters of the function indicating the relationship between the frequency of the clock signal and the temperature for each preset setting. The CPU 16 reads out the parameters of the function from the memory 15 to generate the temperature information. When the control circuit 14 controls the oscillator 11 according to the setting selected from preset settings, the CPU 16 reads out the parameters corresponding to the selected setting from the memory 15. The count value can be converted into the temperature information by using the parameters.

In FIG. 1, although the control circuit 14 and the CPU 16 are shown separately for the sake of convenience, the present disclosure is not limited to this. The CPU 16 may have a function of the control circuit 14 and may be configured to serve as the control circuit 14 as well. That is, the CPU 16 may control the temperature characteristic of the frequency of the clock signal in the oscillator 11 and control the counter 13.

The clock signal generated by the oscillator 11 or the reference signal generated by the oscillator 12 can be used as an operation clock signal for the CPU 16. When the clock signal generated by the oscillator 11 is used as the operation clock signal for the CPU 16, the control circuit 14 desirably controls the oscillator 11 in such a way that the frequency of the clock signal will not have the temperature characteristic during the period when the temperature measurement is not performed.

### [Oscillator 11]

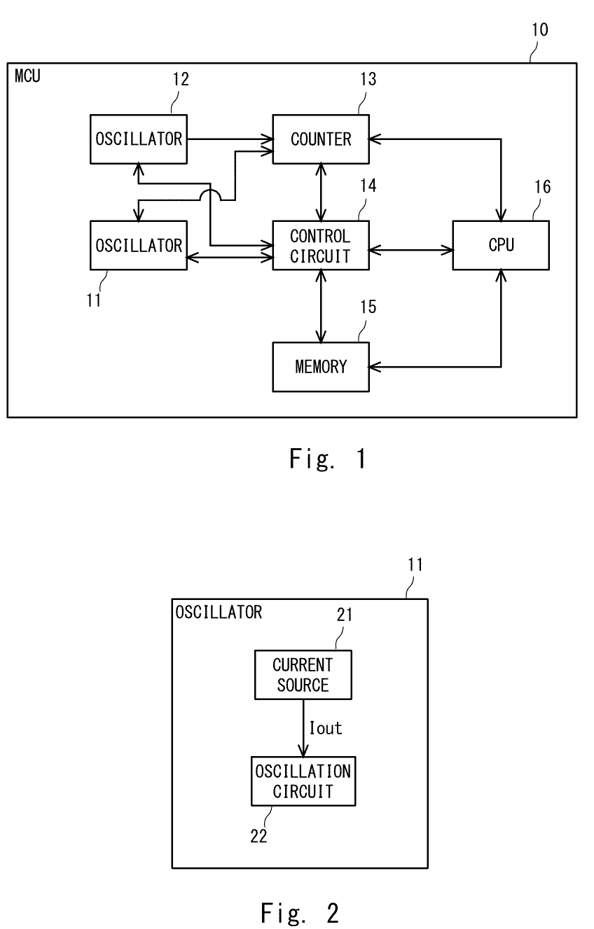

A configuration of the oscillator 11 will be described. FIG. 2 shows an example of the configuration of the oscillator 11. The oscillator 11 has a current source 21 and an oscillation circuit 22. The current source 21 is configured such that a temperature characteristic of the output current Iout is variable. The current source 21 includes, for example, a voltage circuit having a positive temperature characteristic (a temperature characteristic with a positive slope for the temperature) and a voltage circuit having a negative temperature characteristic (a temperature characteristic with a negative slope for the temperature). The current source 21 uses these voltage circuits to change the temperature characteristic of the output current Iout.

The current source 21 is configured such that, for example, a ratio of a change in the output current Iout for a temperature change can be changed. Alternatively or additionally, the current source 21 may be configured such that that the relationship between the temperature and the output current Iout can be changed while maintaining the ratio of the change in the output current Iout for a temperature change constant. Such a current source is disclosed, for example, in the aforementioned Japanese Unexamined Patent Application Publication No. 2012-212352.

The oscillation circuit 22 generates a clock signal by using the current Iout output from the current source 21. The oscillation circuit 22 changes the frequency (oscillation frequency) of the clock signal depending on a magnitude of the current Iout supplied from the current source 21. The oscillation circuit 22 includes, for example, an RS flip-flop or a voltage controlled oscillator (VCO). An oscillation frequency of the oscillation circuit 22 is, for example, monotonically increased as the current Iout supplied from the current source 21 is increased. In this case, when the current Iout supplied from the current source 21 has a positive temperature characteristic, the frequency of the clock signal generated by the oscillation circuit 22 is increased as the temperature rises. Conversely, when the current Iout supplied from the current source 21 has a negative temperature characteristic, the frequency of the clock signal generated by the oscillation circuit 22 is reduced as the temperature rises. The control circuit 14 (see FIG. 1) controls the current source 21 to thereby control the temperature characteristic of the frequency of the clock signal.

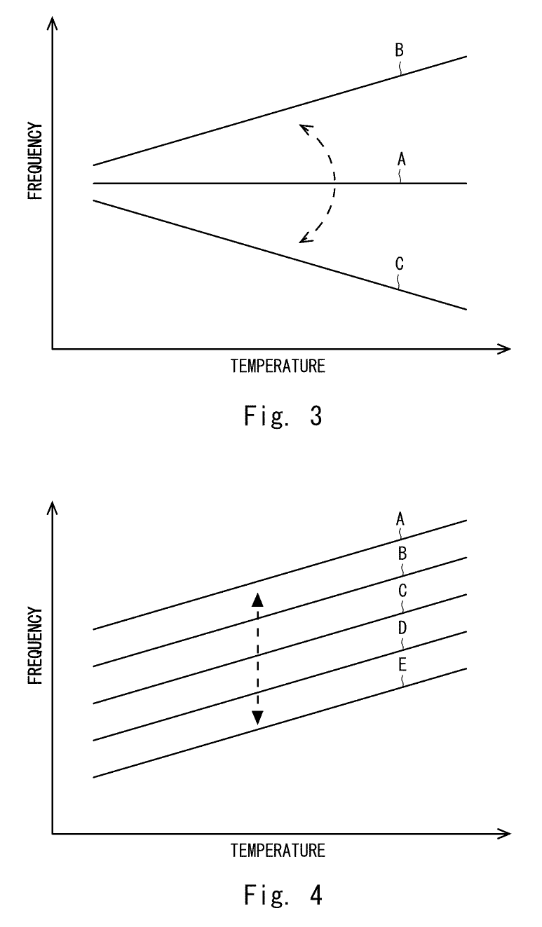

FIG. 3 shows an example of the relationship between the frequency of the clock signal generated by the oscillator 11 and the temperature. The control circuit 14 can control the current source 21 so that the output current Iout will not change depending on the temperature. In this case, the temperature characteristic of the frequency of the clock signal output from the oscillator 11 becomes as indicated by a line A in FIG. 3. Thus, the frequency of the clock signal does not have a temperature characteristic. That is, the frequency of the clock signal generated by the oscillator 11 does not change even if the temperature is changed.

The control circuit 14 can control the current source 21 so that the output current Iout has a positive temperature characteristic. In this case, the temperature characteristic of the frequency of the clock signal output by the oscillator 11 becomes, for example, as indicated by a line B in FIG. 3. Thus, the frequency of the clock signal has a positive temperature characteristic. That is, the frequency of the clock signal generated by the oscillator 11 is increased as the temperature rises.

Contrary to the above case, the control circuit 14 can control the current source 21 so that the output current Iout has a negative temperature characteristic. In this case, the temperature characteristic of the frequency of the clock signal output from the oscillator 11 becomes, for example, as indicated by a line C in FIG. 3. Thus, the frequency of the clock signal has a negative temperature characteristic. That is, the frequency of the clock signal generated by the oscillator 11 is reduced as the temperature rises.

FIG. 4 shows another example of the relationship between the frequency of the clock signal generated by the oscillator 11 and the temperature. The control circuit 14 can control the current source 21 so as to change the relationship between the temperature and the magnitude of the output current Iout while maintaining the slope with respect to the temperature of the output current Iout constant. In this case, the temperature characteristic of the frequency of the clock signal output from the oscillator 11 is controlled, for example, as shown in lines A to E in FIG. 4. For example, by changing the temperature characteristic of the frequency of the clock signal from the one indicated by the line A to the one indicated by the line B, it is possible to reduce the frequency of the clock signal under the same temperature environment.

### [Memory 15]

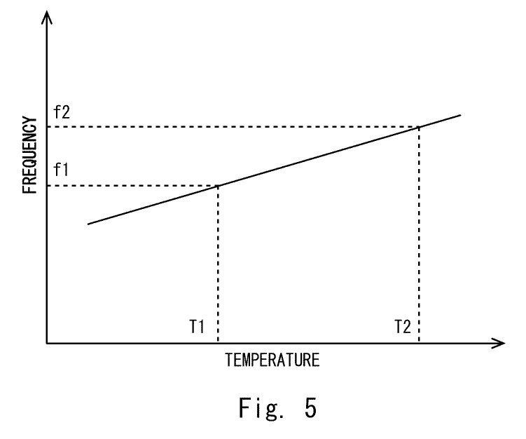

The parameters of the function representing the temperature characteristic of the frequency of the clock signal stored in the memory 15 will be described below. FIG. 5 is a graph showing the relationship between the temperature and the frequency of the clock signal. For example, the memory 15 stores at least two pairs of the temperature and the frequency of the clock signal at that temperature for each of the above-described preset settings. The memory 15 stores, for example, a pair of a temperature T1 and a frequency f1 and a pair of a temperature T2 and a frequency f2 shown in FIG. 5, as the parameters of the function representing a temperature characteristic. The memory 15 stores these parameters for each of the controllable temperature characteristics of the plurality of clock signals. By using these parameters, the frequency of the clock signal can be converted into the temperature information.

In the above description, an example in which two or more pairs of temperature and frequency are stored in the memory 15 has been described. However, the present disclosure is not limited to this. The memory 15 may store other parameters for specifying the function representing the temperature characteristic of the frequency of the clock signal. In the above description, the temperature characteristic of the frequency of the clock signal is expressed by a linear function. However, the temperature characteristic may be expressed by a higher-order function. In this case, the memory 15 may store parameters necessary for specifying the higher-order function. The parameters may be stored in the memory 15, for example, at the factory before shipment of the MCU 10. Alternatively, a user who is using the MCU 10 may store the parameters in the memory 15.

### [Counter 13]

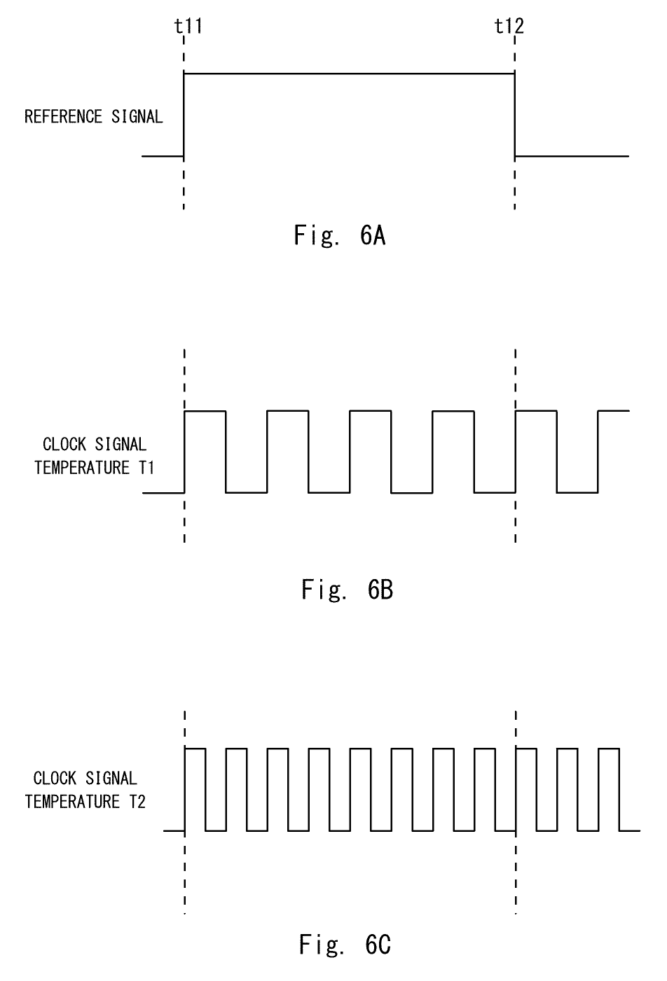

The counting of the clock signal by the counter 13 using the reference signal will be described below. FIGS. 6A to 6C show examples of timing charts showing a reference signal and a clock signal. In this example, the frequency of the reference signal (FIG. 6A) is lower than the frequencies of the clock signals (FIGS. 6B and 6C). Further, the oscillator 11 is controlled so that the frequency of the clock signal has a positive temperature characteristic. The frequency of the clock signal (FIG. 6B) at the temperature T1 is lower than the frequency of the clock signal (FIG. 6C) at the temperature T2. The temperature T2 is higher than the temperature T1.

The counter 13 counts the number of clock pulses of the clock signal (FIG. 6B) or the clock signal (FIG. 6C) in a predetermined period. The predetermined period is, for example, a period from a rising edge (time t11) to a falling edge (time t12) of the reference signal, i.e., half a cycle of the reference signal. As the frequency of the reference signal does not change depending on the temperature, the predetermined period does not change depending on the temperature, and thus it is a fixed time. On the other hand, as the frequency of the clock signal is changed depending on the temperature, the number of clock pulses of the clock signal in the predetermined period varies depending on the temperature. Thus, the count value of the counter 13 varies depending on the temperature. The count value of the clock signal (FIG. 6C) when the temperature is T2 is greater than the count value of the clock signal (FIG. 6B) when the temperature is T1.

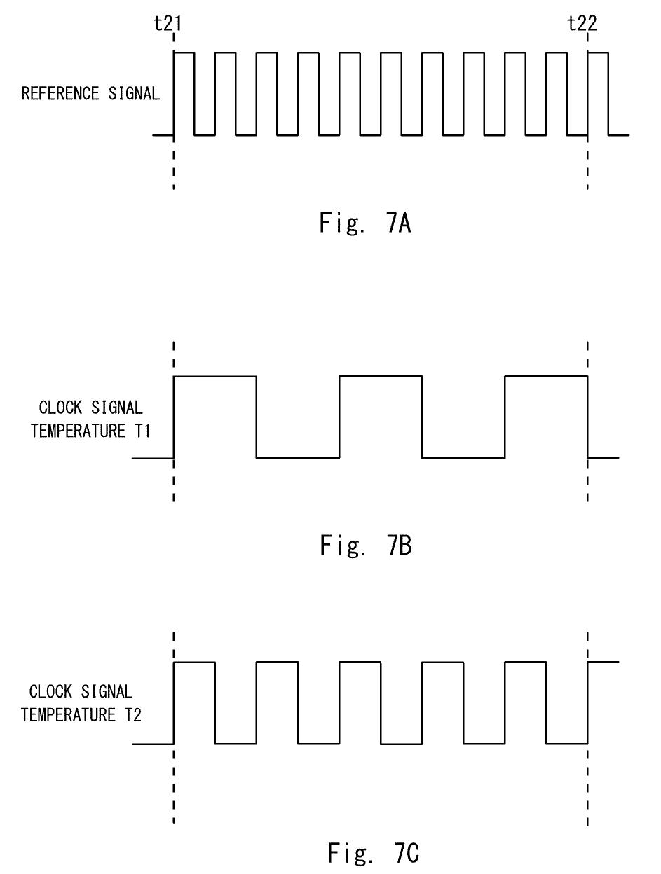

FIGS. 7A to 7C show other examples of timing charts showing the reference signal and the clock signal. In this example, the frequency of the reference signal (FIG. 7A) is higher than the frequencies of the clock signals (FIGS. 7B and 7C). The examples shown in FIGS. 7B and 7C are the same as the examples shown in FIGS. 6B and 6C in the following points. The oscillator 11 is controlled so that the frequency of the clock signal has a positive temperature characteristic. The frequency of the clock signal (FIG. 7B) at the temperature T1 is lower than the frequency of the clock signal (FIG. 7C) at the temperature T2.

The counter 13 counts the number of clock pulses of the clock signal (FIG. 7B) or the clock signal (FIG. 7C) in a predetermined period. The predetermined period is, for example, a period from a rising edge (time t21) of a certain clock pulse of the reference signal to a falling edge (time t22) of a clock pulse after a predetermined number of clock pulses of the reference signal. As the frequency of the reference signal does not change depending on the temperature, the predetermined period does not change depending on the temperature, and thus it is a fixed time. Also in this example, the count value of the counter 13 varies depending on the temperature, and the count value of the clock signal (FIG. 7C) when the temperature is T2 is greater than the count value of the clock signal (FIG. 7B) when the temperature is T1.

A case will be considered below, in which, for example, a plurality of settings corresponding to a plurality of slopes such as slopes A and B are preset in the oscillator 11 within a range of the positive temperature characteristic. The slope A is steeper than the slope B. The control circuit 14 controls, for example, the temperature characteristic of the frequency of the clock signal to be the slope A and controls the counter 13 to count the number of pulses of the clock signal. When the counter 13 overflows in this state, the count value of the counter 13 no longer corresponds to the frequency of the clock signal. Thus the temperature information will become inaccurate.

When the counter 13 overflows, the control circuit 14 controls the temperature characteristic of the frequency of the clock signal to reduce the frequency of the clock signal. The control circuit 14, for example, changes the slope of the temperature characteristic of the frequency of the clock signal from the slope A to the slope B. In this case, if there is no change in the temperature, the frequency of the clock signal is reduced as compared with the case where the slope of the temperature characteristic of the clock signal is controlled to be the slope A. As the frequency of the clock signal is reduced to the frequency at which the counter 13 does not overflow, accurate temperature information can be obtained.

When the slope is reduced as described above, a change (gain) in the frequency of the clock signal with respect to the temperature change becomes small. Thus, the resolution (accuracy) of the obtained temperature information is reduced. On the other hand, the range of the frequency of the clock signal that can be counted without overflowing the counter 13 is expanded, thereby expanding the measurable temperature range (dynamic range). In this embodiment, it is possible to expand the dynamic range by reducing the slope of the temperature characteristic of the frequency of the clock signal within the allowable range of the accuracy of temperature measurement.

Alternatively, the control circuit 14 can control the oscillator 11 so as to reduce the frequency of the clock signal while maintaining the slope of the temperature characteristic of the frequency of the clock signal constant. For example, if settings to achieve the temperature characteristics indicated by the lines A to E in FIG. 4 are preset in the oscillator 11 as the temperature characteristics of the frequencies of the clock signal, the control circuit 14 changes the temperature characteristic from the one indicated by the line A to the one indicated by the line B. Also in this case, if there is no change in the temperature, the frequency of the clock signal is reduced. As the frequency of the clock signal is reduced to the frequency at which the counter 13 does not overflow, accurate temperature information can be obtained.

When the frequency is reduced while maintaining the slope of the temperature characteristic of the frequency of the clock signal constant, the measurable temperature range is moved to a low temperature side or a high temperature side, while maintaining the dynamic range as it is. At this time, since the slope of the temperature characteristic of the frequency of the clock signal is constant, a change (gain) in the frequency of the clock signal with respect to the temperature change does not change. Thus, the resolution (accuracy) of the obtained temperature information is ensured. As described above, in this embodiment, it is possible to perform control so that the current temperature is included in the dynamic range while ensuring the accuracy of the temperature measurement.

### [Operation Procedure]

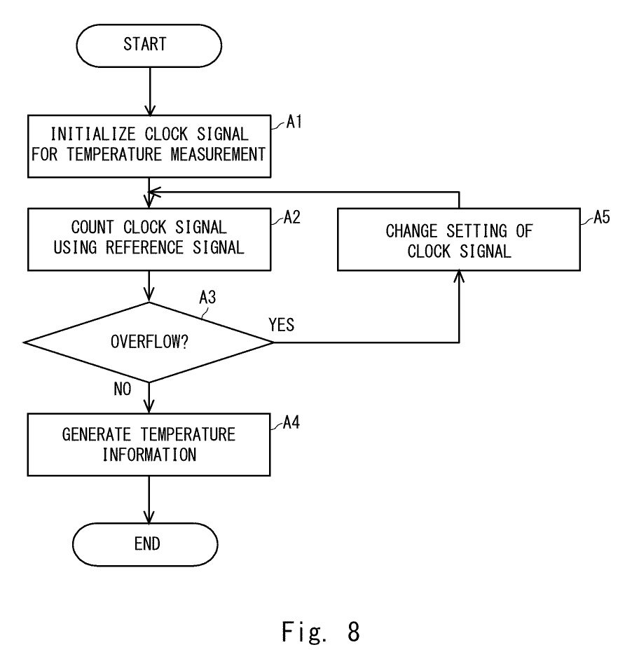

Next, an operation procedure will be described. FIG. 8 shows a procedure of the temperature measurement. The control circuit 14 controls the temperature measurement to start, for example, periodically or upon detection of occurrence of a predetermined event. The control circuit 14 controls the temperature measurement to start, for example, when a predetermined time has elapsed since the previous temperature measurement. Alternatively, the control circuit 14 may control the temperature measurement to start when a signal output from an AD converter or the like (not shown) disposed in the MCU 10 satisfies a predetermined condition. The possible predetermined condition is, for example, a signal value is a threshold or greater or a change in the signal value is a threshold or greater.

The control circuit 14 initializes the clock signal generated by the oscillator 11 for the temperature measurement (Step A1). In Step A1, the control circuit 14 selects one of the plurality of preset settings in the oscillator 11 in accordance with, for example, the temperature measurement range and the required measurement accuracy, and determines the slope of the temperature characteristic of the frequency of the clock signal and the like.

The control circuit 14 outputs a control signal and the like to the counter 13 and controls the counter 13 to start counting the clock signals (Step A2). The counter 13 counts the clock signals output from the oscillator 11 by using the reference signal output from the oscillator 12. The control circuit 14 outputs the control signal and the like to the counter 13 after a lapse of a predetermined time defined based on the reference signal from when the counting is started in order to stop counting the clock signals.

The control circuit 14 determines as to whether an overflow has occurred in the counter 13 (Step A3). When it is determined that an overflow has occurred in Step A3, the control circuit 14 changes the setting of the oscillator 11 (Step A4). In Step A4, the control circuit 14 changes, for example, the slope of the temperature characteristic of the frequency of the clock signal to be less steep. Alternatively, the control circuit 14 changes the relationship between the frequency of the clock signal and the temperature so that the frequency is reduced without changing the slope of the temperature characteristic of the frequency of the clock signal.

After the control circuit 14 changes the setting of the oscillator in Step A4, it returns to Step A2 and controls the counter 13 to start counting the clock signals. The control circuit 14 repeatedly performs Steps A2 to A4 until it determines that the counter 13 has not overflowed in Step A3. The determination in Step A3 as to whether or not the counter 13 has overflowed may be performed without stopping the counter 13.

When it is determined in Step A3 that the counter 13 has not overflowed, the CPU 16 generates the temperature information based on the count value of the counter 13 (Step A5). In Step A5, for example, the CPU 16 reads out, from the memory 15, the parameter corresponding to the setting of the oscillator 11 selected in Step A1 or the parameter corresponding to the setting changed in Step A4. Then, the CPU 16 generates the temperature information based on the read out parameter and the count value. The counting of the clock signals may be performed several times in a state where the counter 13 has not overflowed, and the obtained several count values are added and averaged to generate the temperature information. By performing the above operation, it is possible to adjust the dynamic range and/or measurement accuracy while performing the temperature measurement in the MCU 10.

### [Summary]

In this embodiment, the MCU 10 includes the oscillator 11 capable of changing a temperature characteristic of a frequency of a clock signal to be generated, and the oscillator 12 for generating a reference signal with no temperature characteristic. In the MCU 10, the counter 13, periodically or based on event triggers, counts the clock signal generated by the oscillator 11 using the reference signal generated by the oscillator 12. When the counter 13 overflows, the control circuit 14 adjusts the temperature characteristic of the frequency of the clock signal in the oscillator 11. The CPU 16 generates the temperature information based on the count value and the temperature characteristic of the clock signal. With such a configuration, it is possible to realize a temperature measurement circuit without using circuit resources such as an AD converter.

In this embodiment, the control circuit 14 adjusts the temperature characteristic of the frequency of the clock signal when the counter 13 overflows. By appropriately adjusting the temperature characteristic, it is possible to use the MCU 10 within a range where the counter 13 does not overflow, and the temperature can be accurately measured. Further, in this embodiment, the oscillator 11 capable of arbitrarily changing the temperature characteristic of the frequency of the clock signal to be generated is used to thereby enable arbitrary selection of the measurement accuracy and the dynamic range for the temperature measurement. Therefore, the temperature measurement circuit achieved by the MCU 10 can flexibly respond to the required accuracy, the desired dynamic range, and the like. Since the accuracy and dynamic range required for the temperature measurement differ depending on the application of the user, it is more flexible if the measurement accuracy and/or the dynamic range in the temperature measurement circuit can be adjusted to some extent and the range to which the temperature measurement circuit is applied is expanded.

### Second Embodiment

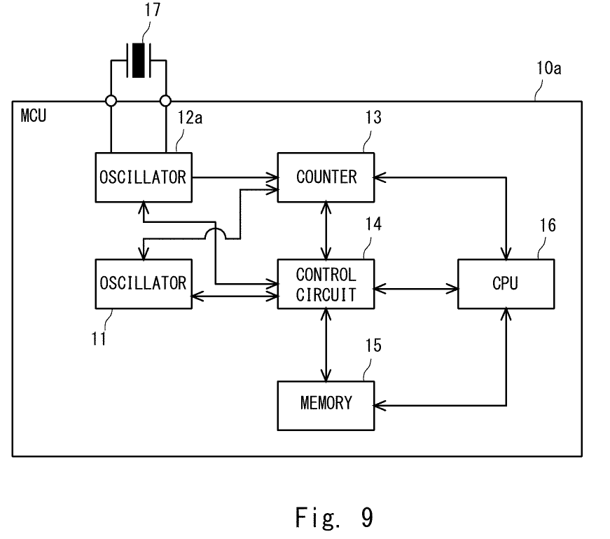

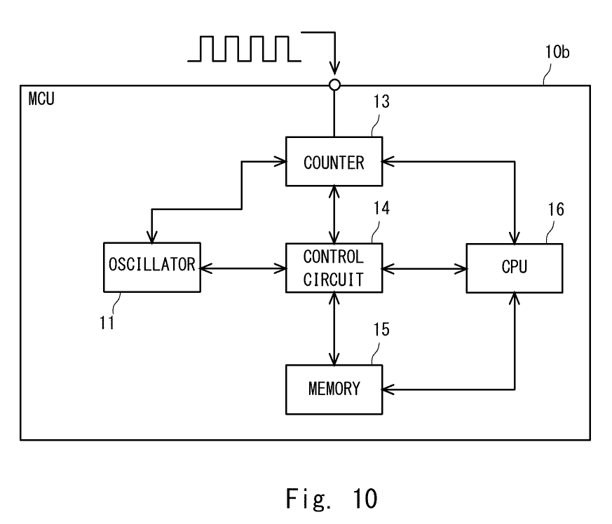

Next, a second embodiment will be described. FIG. 9 shows a microcomputer unit including a temperature measurement circuit according to the second embodiment. An MCU 10a according to this embodiment differs from the MCU 10 according to the first embodiment shown in FIG. 1 in the point that an oscillator 12a of this embodiment includes an external quartz crystal 17. Components other than the crystal oscillator 17 may be the same as those included the MCU 10 of the first embodiment.

The oscillator 12a includes an oscillation circuit. The oscillator (oscillation circuit) 12a is oscillated at a frequency corresponding to a frequency of the quartz crystal 17 and generates a reference signal. The quartz crystal 17 is known as a stable oscillator with high frequency accuracy. The quartz crystal 17 can be used for the oscillator 12a that generates the reference signal. The resonator connected to the oscillator 12a is not limited to the quartz crystal 17. Other resonators having a relatively small fluctuation of the frequency with respect to a temperature change, for example, a ceramic resonator may be used.

In this embodiment, the oscillator 12a generates the reference signal by using the quartz crystal 17. By using the quartz crystal 17, it is possible to generate a reference signal having almost no temperature characteristic, variations in the temperature measurement can be reduced. In addition, when the quartz crystal 17 is externally mounted, a plurality of quartz crystals 17 having different frequencies may be prepared, and one of them may be selected to be connected to the oscillator 12a. By doing so, a frequency of the reference signal can be arbitrarily selected.

Instead of externally mounting the quartz crystal 17, it is also possible to have a structure in which a quartz crystal or a ceramic resonator is provided in the oscillator 12a.

### Third Embodiment

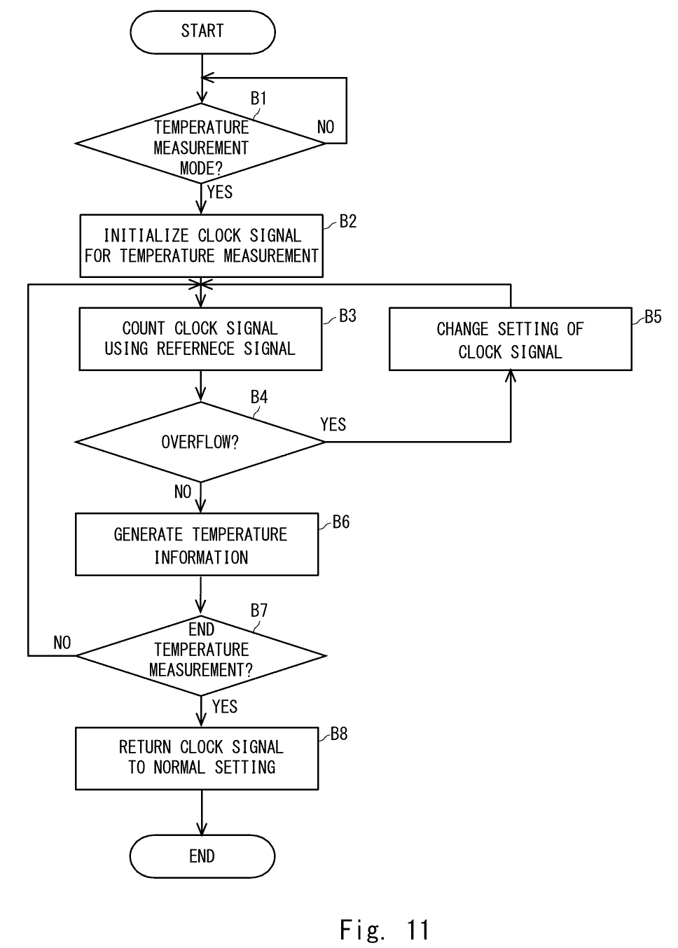

Next, a third embodiment will be described. FIG. 10 shows a microcomputer unit including a temperature measurement circuit according to the third embodiment. An MCU 10b according to this embodiment has the same configuration as that of the MCU 10 according to the first embodiment shown in FIG. 1 except the oscillator 12 for generating the reference signal included in the MCU 10 is not included in the MCU 10b. An external clock signal is input to the MCU 10b from its external clock terminal. The counter 13 uses the external clock signal as the reference signal to count the clock signals. Other configurations maybe the same as those in the first embodiment.

The external clock signal is supplied from a clock source having an output frequency with no temperature characteristic. The external clock signal is generated by, for example, a temperature compensated crystal oscillator (TCXO). The external clock signal may be a clock signal supplied to the CPU 16 as an operation clock signal. When the external clock signal is used as the reference signal, it is not necessary to provide an oscillator for generating the reference signal inside the MCU 10a. Thus the configuration of the MCU 10b can be simplified.

### Other Embodiments

In the first to third embodiments, the MCU 10 is configured as a system capable of freely changing the mode between a main clock mode (normal operation mode) and a temperature measurement circuit mode (temperature measurement mode). In this case, the control circuit 14 is further configured to switch an operation mode of the MCU 10 between the normal operation mode and the temperature measurement mode. When the operation mode is set to the temperature measurement mode, the control circuit 14 controls the oscillator 11 to generate a clock signal having a frequency that has a temperature characteristic. When the operation mode is set to the normal operation mode, the control circuit 14 controls the oscillator 11 to generate a clock signal having a frequency with no temperature characteristic.

### [Operation Procedure]

The operation procedure of the MCU 10 according to other embodiments will be described. FIG. 11 shows an operation procedure of the MCU 10 according to the other embodiments. In the normal operation mode, one of the clock signal generated by the oscillator 11 and the reference signal generated by the oscillator 12 is used as, for example, an operation clock signal for the CPU 16. The other of the clock signal and the reference signal is used by, for example, a peripheral circuit (not shown).

The control circuit 14 determines as to whether or not to switch the operation mode to the temperature measurement mode (Step B1). In Step B1, for example, when a predetermined time has elapsed since the previous temperature measurement or occurrence of an event associated with the temperature measurement is detected, the control circuit 14 determines to switch the operation mode to the temperature measurement mode. When the control circuit 14 determines not to switch the operation mode to the temperature measurement mode, it returns to Step B1 to continue to determine as to whether or not to switch the operation mode to the temperature measurement mode.

In Step B1, when the control circuit 14 determines to switch the operation mode to the temperature measurement mode, the control circuit 14 initializes the clock signal generated by the oscillator 11 for the temperature measurement (Step B2). Next, the control circuit 14 outputs a control signal and the like to the counter 13 and controls the counter 13 to start counting the clock signals (Step B3). The counter 13 counts the clock signal output from the oscillator 11 by using the reference signal output from the oscillator 12. The control circuit 14 outputs a control signal and the like to the counter 13 after a lapse of a predetermined period defined based on the reference signal from the time when the counting is started in order to stop counting the clock signal.

The control circuit 14 determines as to whether or not an overflow has occurred in the counter 13 (Step B4). When it is determined that an overflow has occurred in Step B4, the control circuit 14 changes the setting of the oscillator 11 (Step B5). After the setting of the oscillator is changed in Step B5, the control circuit 14 returns to Step B3 and controls the counter 13 to start counting the clock signals. The control circuit 14 repeatedly performs Steps B3 to B5 until it determines that the counter 13 has not overflowed in Step B4.

When it is determined in Step B4 that the counter 13 has not overflowed, the CPU 16 generates the temperature information based on the count value of the counter 13 (Step B6). In Step B6, for example, the CPU 16 reads out, from the memory 15, the parameter corresponding to the setting of the oscillator 11 selected in Step B2 or the parameter corresponding to the setting changed in Step B5. Then, the CPU 16 generates the temperature information based on the read out parameter and the count value. Note that the operations of Steps B2 to B6 may be the same as the operations of Steps A1 to A5 shown in FIG. 8, respectively.

The control circuit 14 determines as to whether or not to end the temperature measurement (Step B7). In Step B7, when the control circuit 14 determines that the temperature measurement has been performed the predetermined number of times, it determines to end the temperature measurement. If the control circuit 14 determines not to end the temperature measurement, it returns to Step B3 to continue the temperature measurement. If the control circuit 14 determines to end the temperature measurement, it returns the oscillator 11 to a normal setting (Step B8). When the setting of the oscillator 11 returns from the temperature measurement setting to the normal setting, the oscillator 11 generates, for example, a clock signal with no temperature characteristic.

### [Summary]

In the other embodiments, the MCU 10 can switch the operation mode between the normal operation mode and the temperature measurement mode. By using such an MCU 10, it is possible to achieve a microcomputer system that can realize a temperature measurement circuit capable of flexibly responding to required accuracy, desired dynamic range, and the like.

### Modified Example

In the above embodiments, an example is explained, in which the counter 13 counts the clock signal by using the reference signal. However, the reference signal and the clock signal may be replaced with each other. Specifically, the counter 13 may count the reference signal having a frequency that does not change depending on the temperature in a predetermined period defined based on the clock signal having a frequency that changes depending on the temperature. Also in this case, the count value of the counter 13 can correspond to the frequency of the clock signal, and temperature information can be obtained from the count value.

In the above-described embodiments, an example in which the temperature measurement circuit is incorporated in the microcomputer unit has been described. However, the present disclosure is not limited thereto. The temperature measurement circuit may be configured as another integrated circuit (IC: Integrated Circuit) equipped with a temperature measurement function.

Although the invention made by the present inventor has been described in detail based on the embodiments, it is obvious that the present disclosure is not limited to the above embodiments, and various modifications can be made without departing from the scope of the invention. Two or more of the above described embodiments can be combined as desirable by one of ordinary skill in the art.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A temperature measurement circuit comprising:
a first oscillator configured to generate a clock signal and capable of changing a relationship between a frequency of the clock signal and a temperature;
a counter configured to count one of the clock signal generated by the first oscillator and a reference signal having a frequency not changing depending on a temperature by using the other;
a temperature calculator configured to generate temperature information based on the relationship between the frequency of the clock signal and the temperature in the first oscillator and a count value of the counter; and
a control unit configured to change the relationship between the frequency of the clock signal and the temperature when the counter overflows.

2. The temperature measurement circuit according to claim 1, further comprising a second oscillator configured to generate the reference signal.

3. The temperature measurement circuit according to claim 2, wherein the second oscillator comprises a quartz crystal.

4. The temperature measurement circuit according to claim 1, wherein the reference signal is an external clock signal.

5. The temperature measurement circuit according to any one of claim 1, wherein the first oscillator is configured such that a ratio of a change in the frequency of the clock signal for a temperature change can be changed and/or a relationship between the ratio of the change in the frequency of the clock signal for the temperature change can be changed while maintaining the ratio of the change in the clock signal for the temperature change constant.

6. The temperature measurement circuit according to claim 5, wherein
the first oscillator comprises a current source configured such that a ratio of a change in an output current for the temperature change can be changed and/or a relationship between the temperature and the output current can be changed while maintaining the ratio of the change in the output current for the temperature change constant, and
the first oscillator generates a clock signal having a frequency depending on a magnitude of a current output from the current source.

7. The temperature measurement circuit according to claim 1, wherein the control unit controls the first oscillator according to a setting selected from a plurality of preset settings defining the relationship between the frequency of the clock signal and the temperature in the first oscillator.

8. The temperature measurement circuit according to claim 7, further comprising a storage unit configured to store a parameter of a function for each of the preset settings, the function indicating the relationship between the temperature and the frequency of the clock signal, wherein the temperature calculator generates the temperature information by using the parameter stored in the storage unit.

9. The temperature measurement circuit according to claim 8, wherein the storage unit stores at least two pairs of the temperature and the frequency of the clock signal at the temperature for each of the preset settings.

10. An integrated circuit comprising:
the temperature measurement circuit according to claim 1; and
a processor configured to operate according to the clock signal or the reference signal, wherein
the control unit is further configured to:
set an operation mode to a normal operation mode or a temperature measurement mode:
when the operation mode is set to the temperature measurement mode, control the first oscillator to generate a clock signal having a frequency dependent on a temperature; and
when the operation mode is set to the normal mode, control the first oscillator to generate a clock signal having a frequency not dependent on the temperature.

11. A temperature measurement method comprising:
counting, by a counter, one of a clock signal generated by a first oscillator and a reference signal having a frequency not changing depending on a temperature by using the other, the first oscillator generating the clock signal and capable of changing a relationship between a frequency of the clock signal and the temperature;
generating temperature information based on the relationship between the frequency of the clock signal and the temperature in the first oscillator and a count value of the counter; and
changing the relationship between the frequency of the clock signal and the temperature when the counter overflows.
